(19) United States
(12) Patent Application Publication
(10) Pub. No.: US 2005/0156313 A1
(43) Pub. Date: Jul. 21, 2005

(54) Inspection device and method for manufacturing the same, method for manufacturing electro-optic device and method for manufacturing semiconductor device

(76) Inventor: Nobuaki Hashimoto, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/023,979

(22) Filed: Dec. 28, 2004

(30) Foreign Application Priority Data
Jan. 14, 2004 (JP) 2004-006601
Oct. 20, 2004 (JP) 2004-305520

(51) Int. Cl. H01L 23/48; H01L 21/48

(52) U.S. Cl. 257/737; 438/108

(57) ABSTRACT

An inspection device includes a substrate; a stress relieving layer that is provided on the substrate; a contact that is provided on the stress relieving layer; and a wiring pattern that is electrically connected to the contact. Furthermore, method for manufacturing an inspection device includes the steps of: providing a substrate; forming a stress relieving layer on a surface of the substrate; forming a wiring pattern extending over the stress relieving layer on the surface of the substrate; and forming a contact on the wiring pattern in an area above the stress relieving layer.

### CROSS-REFERENCE TO RELATED APPLICATIONS

The entire disclosures of Japanese Patent Application Nos. 2004-006601 filed Jan. 14, 2004 and 2004-305520 filed Oct. 20, 2004 are hereby incorporated by reference.

### BACKGROUND OF THE INVENTION

1. Field of the Invention

The present invention relates to a device that is used during inspections and to a method for manufacturing the same, as well as to a method for manufacturing an electro-optical device and a method for manufacturing a semiconductor device. Particularly, the present invention relates to an inspection device that is preferably used during an inspection of the electrical characteristics of an electro-optical device.

Priority is claimed on Japanese Patent Application No. 2004-6601, filed Jan. 14, 2004 and Japanese Patent Application No. 2004-305520, filed Oct. 20, 2004, the contents of which are incorporated herein by reference.

2. Description of Related Art

For example, in a process to manufacture an electro-optical device such as a liquid crystal display device, inspections of electrical characteristics, such as a lighting inspection and the like, are performed. Conventionally, when inspecting electrical characteristics, a probe (i.e., a needle) of a probe card is placed in contact with an external connecting terminal on a substrate of a liquid crystal panel, and an exchange of signals is performed with a tester. Because a conventional probe card is constructed by protruding a plurality of probes on a substrate, and then guiding a cable from each probe, there have been limits on the extent to which the number of probes can be increased with the increase in the number of external connecting terminals from the electro-optical device. Therefore, in recent years, an inspection device having smaller sized contacts than those of a conventional probe card has been proposed (see, for example, Japanese Patent Unexamined Application, First Publication Nos. H07-283280, H08-236240, and H11-251378).

In the technologies disclosed in Japanese Patent Unexamined Application, First Publication Nos. H07-283280, H08-236240, and H011-251378, contacts are formed using precision processing technology such as photolithography that is employed in processes for manufacturing semiconductors and electronic components. These technologies enable a larger number of contacts to be formed than is the case with a conventional probe card. However, these technologies have been hampered by the following problems.

In the technology described in Japanese Patent Unexamined Application, First Publication No. H07-283280, holes having a V-shaped cross section are formed in a silicon substrate, and bumps are formed that fill up these holes. Wiring that is connected to the bumps is then formed. Thereafter, the substrate that is formed integrally with the bumps is adhered once again to another silicon substrate. Finally, the silicon substrate that was used as a mold is removed, and a connecting device used for inspection is complete. In this manner, the manufacturing process is extremely complicated, and a large number of component parts are required.

In the technology described in Japanese Patent Unexamined Application, First Publication No. H08-236240, a copper foil of copper-clad polyimide film is patterned to form wiring. Next, holes reaching as far as the wiring are formed in the polyimide film by laser irradiation. After the interior of the holes is then filled with metal by plating, the tops of the plating columns are then exposed from the film surface by performing a further laser irradiation so as to complete the formation of the connecting member used for an inspection. In the manner same as in Japanese Patent Unexamined Application, First Publication No. 7-283280, the manufacturing process involved here is extremely complicated. In addition, because bumps are formed on a flexible substrate, they are inferior in dimensional accuracy and environmental stability.

In the technique described in Japanese Patent Unexamined Application, First Publication No. 11-251378, a terminal in the shape of a protrusion that forms an inspection contact is provided on a chip that is being measured. Namely, in this technique, because contacts are formed not on the probe card side but on the chip side, the problem arises that the chip needs to be a dedicated design and its applicability to general use is lost.

### SUMMARY OF THE INVENTION

The present invention was conceived in order to solve the above-described problems and it is an object thereof to provide a device that is used during inspections that enables a high level of dimensional accuracy to be obtained using a small number of component parts and a simple manufacturing process, and that can be used for a general purpose product, and to a method for manufacturing this inspection device, as well as to a method for manufacturing an electro-optical device using this inspection device, and to a method for manufacturing a semiconductor device.

In order to achieve the above object, the inspection device according to one aspect of the present invention includes: a substrate; a stress relieving layer that is provided on the substrate; a contact that is provided on the stress relieving layer; and a wiring pattern that is electrically connected to the contact.

Moreover, the method for manufacturing an inspection device of the present invention includes the steps of: providing a substrate; forming a stress relieving layer on a surface of the substrate; forming a wiring pattern extending over the stress relieving layer on the surface of the substrate; and forming a contact on the wiring pattern in an area above the stress relieving layer.

In the present invention, it is possible to construct an inspection device from a substrate, a stress relieving layer, a contact, and a wiring pattern. The manufacturing of the inspection device is completed simply by stacking the stress relieving layer, the wiring pattern, and the contact in that sequence on the substrate. Accordingly, it is possible to obtain an inspection device that has a small number of component parts by a simple manufacturing process. Moreover, because etching and photolithography techniques, which are commonly used in semiconductor manufacturing processes, can be used to form the wiring pattern, and because a bump formation technology using plating or the like can be applied to the formation of the contact, a high level of dimensional accuracy can be obtained. Furthermore, in the present invention, because the contact is formed on the inspection device, unlike in the technique described in Japanese Patent Unexamined Application, First Publication No. 11-251378, contacts are not required on the object being measured, which is favorable when inspecting the characteristics of general purpose components.

Moreover, in the inspection device of the present invention, it is preferable that an electronic component used for an inspection is mounted on the substrate, and that the electronic component is electrically connected to the wiring pattern.

For example, upon inspecting electrical characteristics of an electro-optical device such as a liquid crystal display device, in many cases electronic components such as driving elements that supply driving signals to the electro-optical device during the inspection are required. However, according to the above-described structure, because the electronic components used for the inspection is mounted in advance on the substrate, and because the electronic component used for the inspection is electrically connected with the wiring pattern, it is not necessary to prepare a separate electronic component for inspection, and the inspection can be made using only this inspection device.

Moreover, it is preferable that the electronic component used for an inspection is an electronic component that is to be mounted on an object to be inspected after the object is inspected.

According to this structure, it is possible to carry out an inspection under the same conditions as the conditions during actual use without having to prepare an electronic component that have been specially designed and manufactured for use for an inspection.

Moreover, it is preferable that the electronic component used for an inspection is mounted on the substrate with its face down.

According to this structure, because no bonding wire or the like is used when terminals of the electronic components used for an inspection are electrically connected to the wiring pattern, the connection structure can be simplified and a reduction in the thickness of the inspection device as a whole can be achieved.

Moreover, various materials can be used as the material of the substrate, however, it is preferable that the substrate is made from a transparent substrate.

According to this structure, the position of the contact can be observed from the substrate side, and positioning of the terminals of the object being measured and of the contact can be performed easily.

It is also possible to employ a structure in which an electrical shielding layer is provided on the substrate.

According to this structure, it is possible to provide an inspection device that enables a reduction in unnecessary radiation and an improvement in the noise proof properties to be obtained, and that enables electrical characteristics to be inspected more accurately.

It is also preferable that the contact is tapered from an end thereof that is adjacent to the substrate to an opposing end thereof.

In some cases, a thin oxide film that has been generated by the oxidization of a metal material is formed on a surface of the terminals of the object being measured. In such cases, according to the above-described structure, because the contact is tapered, the tip of the contact break through the oxide film when the contact is placed against the terminals, and can make contact more easily with the metal layer under the oxide film. As a result, it is possible to increase the reliability of the measurement of electrical characteristics.

It is also possible that the device further includes a connector that is provided above the substrate.

According to this structure, this inspection device can be easily connected electrically with a tester.

It is also possible for a hollow space to be provided beneath the contact. In this case, at least a portion of the stress relieving layer beneath the contact may have been removed to define the hollow space. Alternatively, at least a portion of the substrate beneath the contact may have been removed to define the hollow space.

According to this structure, because the flexibility of the contact is further improved as a result of the hollow space being provided, it is possible to ensure more consistent contact even when irregularities or unevenness are present on the surface being inspected.

Furthermore, even if the contact is displaced during the inspection, the displacement is accommodated. Therefore, the surface being inspected is resistant to damages, and the reliability of the inspection is improved. Moreover, when the hollow space is formed by removing at least a portion of the stress relieving layer or substrate, it is possible to form the hollow space using a comparatively simple method.

Another aspect of the present invention is an inspection device that is used for an inspection of electrical characteristics of an electronic device including: a substrate; a stress relieving layer that is provided on the substrate; a contact that is provided on the stress relieving layer; a wiring pattern that is electrically connected to the contact; and an electronic component for driving the electronic device, wherein the electronic component is provided on the substrate and is electrically connected to the wiring pattern.

According to this structure, as has been described above, it is possible to provide an inspection device that has a small number of component parts and that enables a high level of dimensional accuracy to be obtained by a simple manufacturing process, and that can be applied to general purpose design components. In addition, a measurement can be made using only this inspection device without separate electronic components used for an inspection having to be prepared.

Furthermore, in the method for manufacturing an inspection device of the present invention, the step of forming a contact may include the steps of: forming a mask having a pattern in which a portion of an area on the wiring pattern that is above the stress relieving layer is opened; and forming the contact by performing a plating process after the step of forming the masking.

According to this method, contact can be formed easily on a substrate using a conventionally known technology.

Moreover, the method may further include the steps of: forming, before the step of forming the stress relieving layer, a sacrifice layer on the substrate at least in an area beneath where the contact is to be formed subsequently; and forming, after the step of forming the stress relieving layer, a hollow space in an area beneath the contact by selectively removing the sacrifice layer.

According to this method, the hollow space can be formed after the sacrifice layer has been removed, and it is possible to manufacture an inspection device in which the flexibility of the contact is improved.

Moreover, the method may further include the step of: forming a hollow space by selectively removing at least a portion of the stress relieving layer that is beneath the contact. Alternatively, the method may further include the step of: forming a hollow space by selectively removing at least a portion of the substrate that is beneath the contact.

According to these structures, unlike the method described above, it is possible to form the hollow space without using the sacrifice layer, and it is possible to manufacture an inspection device in which the flexibility of the contact is improved.

A method for manufacturing an electro-optical device of the present invention includes the step of inspecting electrical characteristics using the above-described inspection device of the present invention.

A method for manufacturing a semiconductor device of the present invention includes the step of inspecting electrical characteristics using the above-described inspection device of the present invention.

According to these manufacturing methods, it is possible to carry out an inspection of electrical characteristics efficiently, and the present invention can be favorably used for electro-optical devices and semiconductor devices that have a large number of terminals.

### BRIEF DESCRIPTION THE DRAWINGS

FIG. 1 is a plan view of a liquid crystal display device that is to be measured according to a first embodiment of the present invention;

FIG. 2 is a cross-sectional view of the liquid crystal display device according to the same embodiment;

FIG. 3 is a perspective view showing an inspection device according to the same embodiment;

FIGS. 4A to 4E are cross-sectional views illustrating steps of a method to manufacture an inspection device in sequence according to the same embodiment;

FIG. 5 is a view showing an inspection using the inspection device according to the same embodiment;

FIG. 6 is a cross-sectional view showing an inspection device according to a second embodiment of the present invention;

FIGS. 7A to 71 are cross-sectional views illustrating steps of a method to manufacture an inspection device in sequence according to a third embodiment of the present invention; and

FIG. 8 is a view for describing an alternative embodiment of the manufacturing method according to the same embodiment.

### DETAILED DESCRIPTION OF THE INVENTION

### First Embodiment

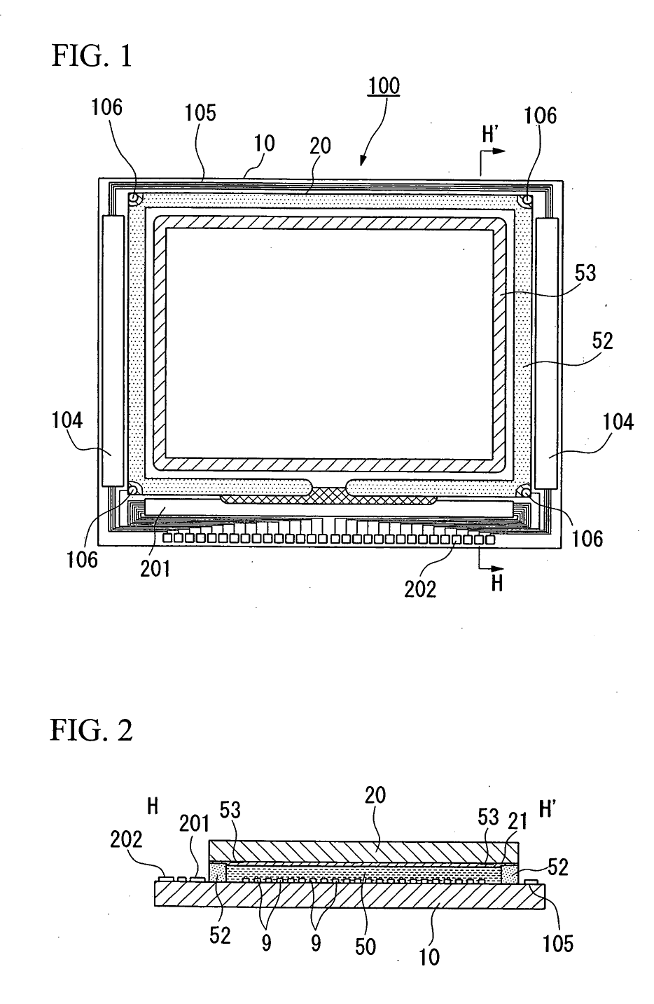

The first embodiment of the present invention will now be described with reference made to FIGS. 1 through 5.

In the present embodiment, a description is given of an example in which an inspection is carried out of the electrical characteristics of a liquid crystal display device which is one type of electro-optical device.

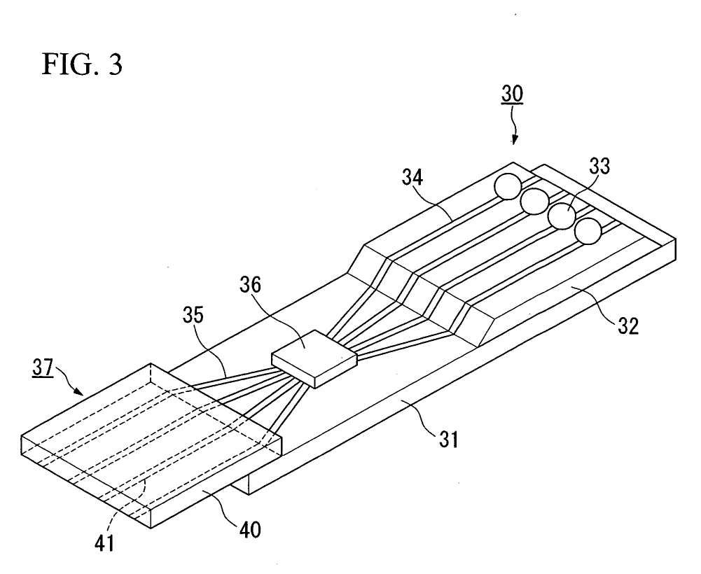

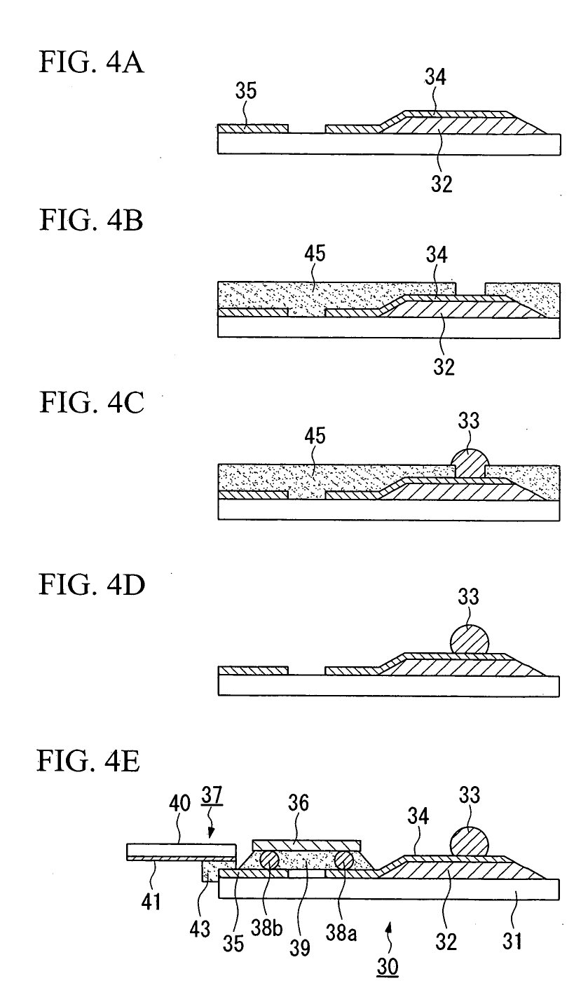

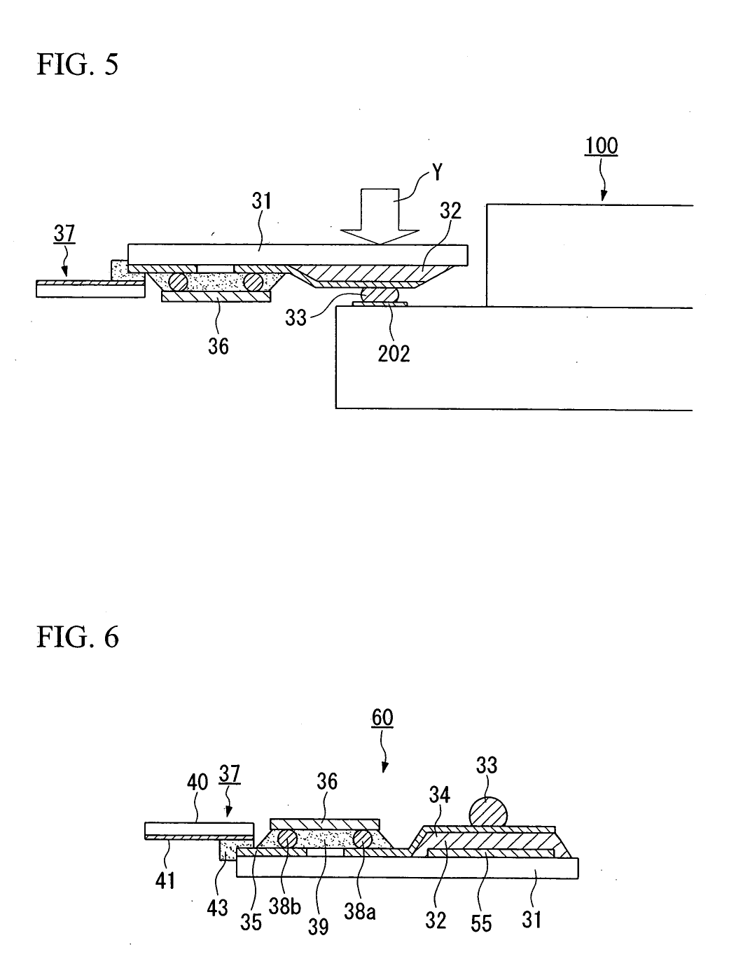

FIG. 1 is a plan view showing the schematic structure of a liquid crystal display device that is to be measured. FIG. 2 is a cross-sectional view taken along the line H-H′ in FIG. 1. FIG. 3 is a perspective view showing the inspection device according to the present embodiment that is used in an inspection of the electrical characteristics of the liquid crystal display device. FIGS. 4A to 4E are cross-sectional views illustrating steps of a method for manufacturing an inspection device in sequence according to the same embodiment. FIG. 5 is a view showing an inspection using the inspection device according to the same embodiment. Note that in each drawing used in the description given below, the scale of each layer and each member is different in order to make each layer and each member large enough to be recognizable in the drawings.

First, the liquid crystal display device being measured will be described.

As shown in FIG. 1 and FIG. 2, a liquid crystal display device 100 that is used in the present embodiment is formed by adhering a thin film transistor (hereinafter abbreviated as “TFT”) array substrate 10, which is provided with thin film transistors functioning as pixel switching elements, to a facing substrate 20 using a sealing material 52. A liquid crystal layer 50 is thereby enclosed within an area on an inside of the sealing material 52. A light shielding film (i.e., a periphery partitioning member) 53 that is made of a light shielding material is formed on the inside of the area where the sealing material 52 is formed. A data line driving circuit 201 is formed along one side of the TFT array substrate 10 in a peripheral circuit area on the outside of the sealing material 52, and scan line driving circuits 104 are formed along the two sides that are adjacent to this one side. A plurality of wires 105 that are used to connect together the two scan line driving circuits 104 that are provided on two sides of the display area are provided on the remaining side of the TFT array substrate 10. An inter-substrate conductive material 106 that is used to provide electrical connection between the TFT array substrate 10 and the facing substrate 20 is placed in corners of the facing substrate 20.

A number of external circuit packaging terminals 202 are provided in a row on an outside of the data line driving circuit 201 on the TFT array substrate 10. As shown in FIG. 2, the outer dimension of the TFT array substrate 10 is larger than the outer dimension of the facing substrate 20, and the area of the edge of the TFT array substrate 10 in which the external circuit packaging terminals 202 are provided is positioned so as to protrude towards the outside beyond the edge of the facing substrate 20. By employing this structure, when inspecting electrical characteristics using the inspection device described below, it is possible to easily place the contacts of the inspection device in contact with the external circuit packaging terminals 202.

Next, the inspection device will be described.

As shown in FIG. 3 and FIG. 4E, an inspection device 30 of the present embodiment generally includes a substrate 31, a stress relieving layer 32, contacts 33, wiring patterns 34 and 35, a driving IC 36 (i.e., an electronic component for driving electro-optical devices), and a connector 37. This inspection device 30 corresponds to a conventional probe card, and has a function of relaying signals exchanged between the external circuit packaging terminals 202 of the liquid crystal display device 100 and a tester. The substrate 31 may be made of a rectangular transparent substrate formed from, for example, glass or quartz. Note that the substrate does not necessarily have to be a transparent substrate, and it is also possible to use, for example, a silicon substrate or the like.

The stress relieving layer 32 is formed on one end side of the substrate 31. The stress relieving layer 32 can be formed by patterning photosensitive polyamide resin whose layer thickness is, for example, in a range of 1 μm to 100 μm and preferably about 10 μm. Both ends of the stress relieving layer 32 are formed as tapered sloping surfaces. By forming the stress relieving layer 32 with tapered surfaces, the winding of the wiring pattern (described below) in the stepped portion of the stress relieving layer 32 is improved, and the effect is obtained that it is possible to prevent breakages in the wiring pattern.

Note that it is possible to use a resin having no photosensitivity for the material of the stress relieving layer 32. For example, it is possible to use a material that shows a stress relieving effect and that has a low Young's modulus (1×10¹⁰ Pa or less) when hardened such as silicone denatured polyamide resin, epoxy resin, silicon denatured epoxy resin and the like.

A plurality of first wiring patterns 34 (only four are shown in FIG. 3 to make the diagram easier to see) are formed from a top surface of the substrate 31 extending to a top surface of the stress relieving layer 32. In addition, a plurality of second wiring patterns 35 are formed on the top surface of the substrate 31 where the stress relieving layer 32 is not provided. Aluminum, aluminum alloys such as aluminum-silicon, and aluminum-copper, copper, copper alloys, or gold, titanium, titanium alloys, chromium, and the like can be used for the material of the wiring patterns 34 and 35. If an aluminum-based material, a copper-based material, or gold or the like is selected, then because these materials have extendibility, it is possible to increase crack resistance. If a titanium-based material, which has excellent moisture resistance, is selected, then it is possible to prevent breakages due to corrosion. Chromium has excellent adhesion with the polyimide of the subbing layer.

On top of the stress relieving layer 32, contacts 33 are provided on the first wiring pattern 34 to correspond to each of the first wiring patterns 34. The contacts 33 may be made of nickel, or may be obtained by coating a nickel layer around a copper core, or by coating a further metal around a core of copper and nickel, or the like. Because the inspection device 30 is used repeatedly a large number of times for inspections of electrical characteristics, it is preferable that the material used for the contacts 33 has high abrasion resistance, and is a hard material where possible. The shape of the contacts 33 may be conical or a truncated cone shape in addition to the spherical shape shown in the drawings. Whichever shape is used, it is preferable that the contacts 33 are tapered from the end that is in contact with the first wiring pattern 34 toward the tip thereof. If the tip is slightly tapered, then during an inspection, when a contact 33 is placed against a terminal, it is easy for the tip of the contact 33 to break through the oxide film on the terminal and make contact with the metal layer beneath. This enables the reliability of the measurement of electrical characteristics to be increased. The contacts 33 are electrically connected by being in direct contact with the first wiring pattern 34. Note that other materials that may be used for the contacts 33 include tungsten, tungsten carbide, and diamond, and any material may be used provided that it satisfies the above-described conditions.

The driving IC 36 is mounted on the top surface of the substrate 31. The driving IC 36 supplies driving signals to the liquid crystal display device 100 that is to be inspected, and, when, for example, a production of a liquid crystal module is completed, may be the same as the driving IC that is mounted on an external substrate that is connected to the liquid crystal panel shown in FIG. 1. As shown in FIG. 4E, a terminal 38a that outputs driving signals to the liquid crystal display device 100 from among the plurality of terminals of the driving IC 36 is connected to an end of the first wiring pattern 34 on the side opposing from the side on which the contacts 33 are provided. A terminal 38b that receives the input of signals from a tester is connected to an end of the second wiring pattern 35. The connections between the terminals 38a and 38b of the driving IC 36 and the first and second wiring patterns 34 and 35 are sealed by a resin layer 39. Malfunctions caused by moisture or foreign matter entering into the connecting portions and causing corrosion or short-circuiting can be prevented by the resin layer 39. Furthermore, although omitted from the drawings, it is preferable that a protective layer formed by solder resist or the like is provided on each of the wiring patterns 34 and 35 other than in the regions of the contacts 33 and the electrical connections with the driving IC 36.

In the same manner as for the resin layer 39 described above, the protective layer is provided to protect the wiring patterns 34 and 35 and to prevent corrosion and short-circuiting. It is preferable that a known face-down configuration is employed for mounting the driving IC 36 from the viewpoint of the reduction in the thinness of the film, however, other mounting method, such as wire bonding, may also be used. In addition, it is preferable that the driving IC 36 is the one that is used in an actual product and supplies driving signals to the liquid crystal display device 100 that is to be inspected, then from the viewpoints of simplifying design and manufacturing. However, it may be possible that the driving IC 36 is one that has been specifically designed for inspection.

The connector 37 is provided at an end on the side opposing to the side in which the contacts 33 are provided on the top surface of the substrate 31 in order to obtain an electrical connection with the tester. Although the connector 37 is provided on the side opposing to the side in which the contacts 33 are provided in this embodiment, the connector 37 may be provided at any location above the substrate. The connector 37 is constructed by forming wiring patterns 41 to correspond to each of the aforementioned second wiring patterns 35 on one surface of a flexible substrate 40 that may be made of, for example, an any resin material. After the wiring patterns 41 on the flexible substrate 40 and the second wiring patterns 35 on the substrate 31 have been placed facing each other, the wiring patterns 41 and the second wiring patterns 35 are electrically connected via an anisotropic conductive film (hereinafter referred to as an “ACF”) 43, and the flexible substrate 40 and the substrate 31 are mechanically bonded.

A method for manufacturing an inspection device having the above-described structure will now be described.

First, as shown in FIG. 4A, a transparent substrate for forming the substrate 31 is prepared, and a photosensitive polyimide resin in liquid form is coated on a top surface thereof. Once a photosensitive polyimide resin layer has been formed over the entire surface, masking exposure, developing, and baking processes are performed, and the photosensitive polyimide resin layer is patterned to form the stress relieving layer 32.

If a non-photosensitive resin is used for the material of the stress relieving layer 32, once the resin layer has been formed, the resin layer can be patterned using a typical photolithography method employing photoresist and an etching method. Next, a metal film of Al, Al—Si, Al—Cu, Cu, Cu-alloy, Au, Ti, Ti alloy, Cr, or the like is formed over the entire surface of the substrate 31 using a sputtering method or an evaporation method or the like. The metal film is then patterned using a typical photolithography method employing photoresist and using an etching method, so as to form the wiring patterns 34 and 35. The photoresist is then removed.

Next, as shown in FIG. 4B, photoresist layer 45 having a pattern in which a portion of an area on the first wiring pattern 34 that is above the stress relieving layer 32 (i.e., those locations where the contacts 33 are to be formed later) is opened is formed using a photolithography method.

Next, as shown in FIG. 4C, using the photoresist layer 45 as a mask, the contacts 33 are formed by precipitating metal in the opening in the photoresist layer 45 by performing electrolytic plating or non-electrolytic plating using a metal such as Ni or Cu/Ni. Alternatively, instead of employing a plating method, it is also possible for the contacts 33 to be formed using a printing method. In addition, in order to form the tapered contacts 33 such as in the shape of circular truncated cones, the plating may be conducted under conditions in which the metal undergoes anisotropic growth, or the shape may be controlled by performing anisotropic etching once again.

Next, by removing the photoresist layer 45 that was used as a mask during the plating, the formation of a contact 33 such as that shown in FIG. 4D is completed.

Next, as shown in FIG. 4E, a connector 37 that has been separately prepared is bonded to the substrate 31 via the ACF 43. In addition, the driving IC 36 is mounted on the wiring patterns 34 and 35, and the portions of the terminals 38a and 38b of the driving IC 36 are sealed by the resin layer 39 thereby completing the formation of the inspection device 30 of the present embodiment.

When manufacturing the liquid crystal display device 100, for example, the TFT array substrate 10 is adhered to the facing substrate 20 via the sealing material 52, so as to manufacture hollow liquid crystal cells. Subsequently, liquid crystal is injected into the liquid crystal cells using a vacuum injection method. After this, the liquid crystal injection apertures are sealed using a sealing material so as to manufacture the liquid crystal display device 100. An electrical characteristic inspection is then performed in order to inspect whether or not the desired electrical characteristics are obtained from the completed liquid crystal display device 100.

When performing the inspection of the electrical characteristics of the liquid crystal display device 100 using this inspection device 30, after the connector 37 of the inspection device 30 has been connected to a tester, as shown in FIG. 5, the inspection device 30 is positioned such that the contacts 33 face downwards. Once the contacts 33 have been positioned relative to the external circuit packaging terminals 202 of the liquid crystal display device 100, the inspection device 30 is pushed slightly in the direction shown by the arrow Y, resulting in the contacts 33 being placed securely in contact with the external circuit packaging terminals 202. In the case of the present embodiment, because the substrate 31 is made from a transparent substrate, the positional relationship between the contacts 33 and the external circuit packaging terminals 202 can be observed from the substrate 31 side, which is convenient when performing the positioning. In this state, by inputting an inspection signal from the tester into the liquid crystal display device 100 via the inspection device 30 and then obtaining the output thereof, various types of electrical characteristics can be inspected, including a lighting inspection.

According to the present embodiment, it is possible to construct the inspection device 30 from the substrate 31, the stress relieving layer 32, the contacts 33, the wiring patterns 34 and 35, the driving IC 36, and the connector 37, and the manufacturing of the inspection device is completed simply by stacking and packaging these members in sequence on the substrate 31. Accordingly, it is possible to obtain an inspection device that has a small number of component parts by a simple manufacturing process. Moreover, because etching and photolithography techniques, which are commonly used in semiconductor manufacturing processes, can be used to form the wiring patterns 34 and 35, and because a bump formation technology using plating or the like can be applied to the formation of the contacts 33, a high level of dimensional accuracy can be obtained. Furthermore, because the contacts 33 are formed on the inspection device 30, unlike in the technique described in Japanese Patent Unexamined Application, First Publication No. 11-251378, contacts are not required on the object being measured, which is favorable when inspecting the characteristics of general purpose components. In addition, because the inspection device 30 is provided with the driving IC 36, there is no need to provide a separate driving IC and an inspection can be made easily using only this inspection device and a normal tester.

### Second Embodiment

The second embodiment of the present invention will now be described using FIG. 6.

The basic structure of the inspection device of the present embodiment is the same as that of the inspection device of the first embodiment, and only the layer structure thereof is slightly different.

FIG. 6 is a cross-sectional view showing the inspection device of present embodiment, and corresponds to FIG. 4E of the first embodiment. Accordingly, in FIG. 6, the same symbols are assigned to component elements that are common with FIG. 4E, and a detailed description thereof is omitted.

In the first embodiment, the stress relieving layer 32 is formed directly on the substrate 31, and the wiring patterns 34 and 35 and the contacts 33 are formed in sequence above the stress relieving layer 32. In contrast to this, as shown in FIG. 6, in the inspection device 60 of the present embodiment, an electrical shielding layer 55 is formed on the side of the top surface of the substrate 31 where the contacts 33 are provided, and the stress relieving layer 32 is formed so as to cover the electrical shielding layer 55. The first wiring patterns 34 are formed extending from the top of the substrate 31 to the top of the stress relieving layer 32, and the contacts 33 are formed on the top of the first wiring patterns 34. In the same manner as for the wiring patterns 34 and 35, aluminum, aluminum alloys such as aluminum-silicon, and aluminum-copper, copper, copper alloys, or gold, titanium, titanium alloys, chromium, and the like can be used for the material of the electrical shielding layer 55. However, while the wiring patterns 34 and 35 are patterned in the shape of lines, the electrical shielding layer 55 is formed in the shape of a wide area under the stress relieving layer 32. The electrical shielding layer 55 may be in a floating state electrically, however, it should preferably be in a constant voltage and, in particular, to be grounded in order to improve the noise proof properties thereof.

As an alternative embodiment of the present embodiment, it is also possible to further improve the noise proof properties by forming multilayered stress relieving layer and wiring patterns, or multilayered wide-area potential layer and ground layer, or by employing a known strip or micro-strip structure for the wiring.

It is also possible using the structure of the present embodiment to obtain the same effects as those obtained in the first embodiment, namely, it is possible to provide an inspection device that has a small number of component parts and that enables a high level of dimensional accuracy to be obtained by a simple manufacturing process, and that can be applied to general purpose components. Furthermore, in the case of the present embodiment, by providing the electrical shielding layer 55, it is possible to provide an inspection device that enables a reduction in unnecessary radiation and an improvement in the noise proof properties to be obtained, and that enables electrical characteristics to be inspected more accurately.

### Third Embodiment

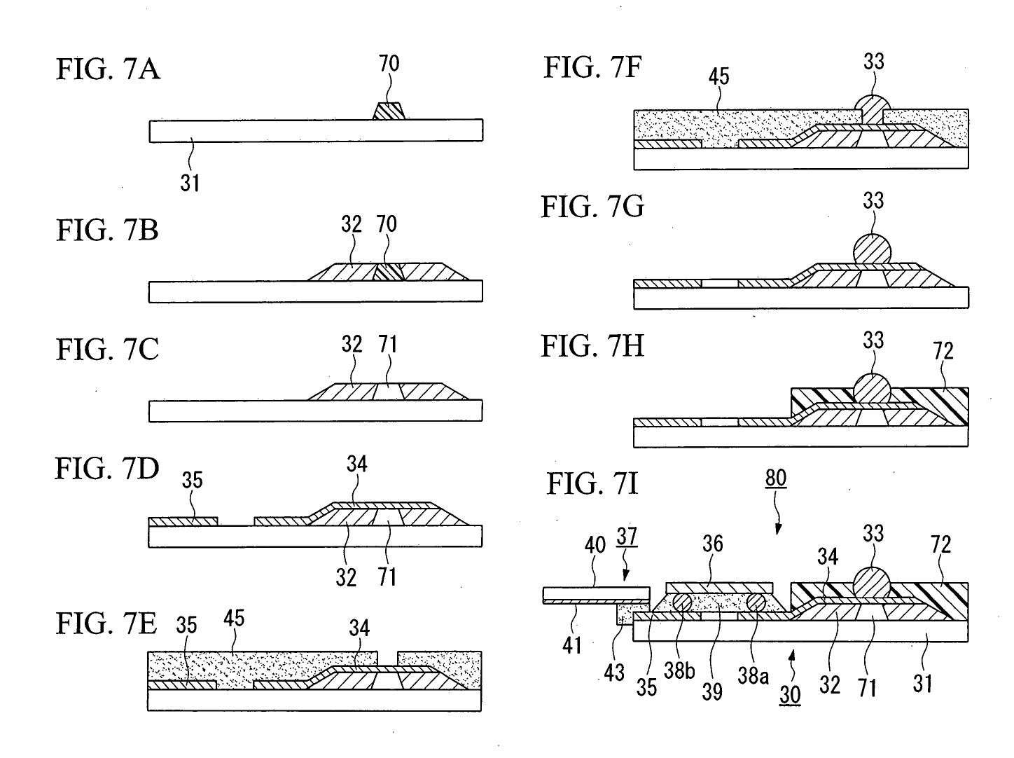

The third embodiment of the present invention will now be described using FIGS. 7A to 71 and FIG. 8.

The basic structure of the inspection device of the present embodiment is the same as that of the inspection device of the first embodiment, and only differs in that a hollow space is provided beneath the contacts.

FIG. 71 is a cross-sectional view showing the inspection device of present embodiment, and corresponds to FIG. 4E of the first embodiment and FIG. 6 of the second embodiment. Accordingly, in FIG. 71, the same symbols are assigned to component elements that are common with FIG. 4E and FIG. 6, and a detailed description thereof is omitted. FIG. 7A to FIG. 71 are cross-sectional views showing a manufacturing process to manufacture an inspection device of the present embodiment.

In the inspection device 80 of the present embodiment, as shown in FIG. 71, a hollow space 71 is provided inside the stress relieving layer 32 at a position beneath the contact 33. Because the inspection device 80 has a plurality of contacts 33 in the same manner as shown in FIG. 3, the hollow space 71 may be provided continuously extending along the plurality of contacts 33 (i.e., in a direction orthogonal to FIG. 71). Alternatively, a space 71 may be provided independently to correspond to each contact 33. In FIG. 71, the entire stress relieving layer 32 is removed from the area beneath the contacts 33, and the first wiring pattern 34 is placed so as to be suspended above the hollow space 71. A structure may be employed in which all of the stress relieving layer 32 is removed in the direction orthogonal to the top of the stress relieving layer 32 as is shown in the figure, or a structure may be employed in which a portion of the stress relieving layer 32 in the direction orthogonal to the top of the stress relieving layer 32 is left in an area beneath the contacts 33, so that the hollow spaces 71 are formed in the portions where the stress relieving layer 32 has been partially removed. In the latter case, the first wiring patterns 34 are not suspended, but are placed above the stress relieving layer 32.

A description will now be given of a method for manufacturing an inspection device having the above-described structure.

As shown in FIG. 7A, a transparent substrate for forming the substrate 31 is prepared, and a photosensitive silicone resin is coated on the top surface thereof. Once a photosensitive silicone resin layer has been formed over the entire surface, the photosensitive silicone resin layer is patterned by mask exposure and developing processing so as to form a sacrifice layer 70. However, because there is a later step to selectively remove only the sacrifice layer 70 while leaving the stress relieving layer, it is necessary to use as the material of the sacrifice layer 70 a material that has a sufficiently large etching selectivity ratio relative to the stress relieving layer that is formed later. A material that can be wet etched using a solvent or the like is also preferable.

Next, as shown in FIG. 7B, a photosensitive polyimide resin in liquid form is coated on a top surface thereof. Once a photosensitive polyimide resin layer has been formed over the entire surface, masking exposure, developing, and baking processes are performed, and the photosensitive polyimide resin layer is patterned to form the stress relieving layer 32. If a non-photosensitive resin is used for the material of the stress relieving layer 32, once the resin layer has been formed, the resin layer can be patterned using a typical photolithography method employing photoresist and an etching method. At this time, if there is absolutely no stress relieving layer 32 at all on the top surface of the sacrifice layer 70, then it is possible to form a structure in which the first wiring pattern 34 is suspended above the space 71. Alternatively, if the stress relieving layer 32 is placed on the top surface of the sacrifice layer 70, then it is possible to form a structure in which the first wiring pattern 34 is placed on the stress relieving layer 32.

Next, as shown in FIG. 7C, by selectively removing only the sacrifice layer 70 while leaving the stress relieving layer 32, the hollow space 71 is formed inside the stress relieving layer 32. At this time, wet etching can be employed that uses an etching solution (in this case, an organic solvent) whose etching selectivity ratio of silicon resin (i.e., the sacrifice layer 70) relative to polyimide resin (i.e., the stress relieving layer 32) is comparatively large. Alternatively, dry etching can also be employed provided that a sufficiently large etching selectivity ratio can be obtained.

Next, as shown in FIG. 7D, a metal film of Al, Al—Si, Al—Cu, Cu, Cu-alloy, Au, Ti, Ti alloy, Cr, or the like is formed over the entire surface using a sputtering method or an evaporation method or the like. The metal film is then patterned using a typical photolithography method employing photoresist and an etching method, so as to form the wiring patterns 34 and 35. The photoresist is then removed. Note that, regarding the sequence of the removal of the sacrifice layer and the formation of the wiring patterns, instead of the above-described sequence, it is also possible to use the structure in which the stress relieving layer 32 is not placed on the top surface of the sacrifice layer 70, and to form a hollow space 71 such as that shown in FIG. 7D by etching the sacrifice layer 70 after first forming the wiring patterns 34 and 35.

Next, as shown in FIG. 7E, photoresist layer 45 having a pattern in which a portion of an area on the first wiring pattern 34 that is above the stress relieving layer 32 (i.e., those locations where the contacts 33 are to be formed later) is opened is formed using a photolithography method.

Next, as shown in FIG. 7F, using the photoresist layer 45 as a mask, the contacts 33 are formed by depositing metal in the opening in the photoresist layer 45 by performing electrolytic plating or non-electrolytic plating using a metal such as Ni or Cu/Ni. Alternatively, instead of employing a plating method, it is also possible for the contacts 33 to be formed using a printing method. In addition, in order to form the tapered contacts 33 such as in the shape of circular truncated cones, the plating may be conducted under conditions in which the metal undergoes anisotropic growth, or the shape may be controlled by performing anisotropic etching once again.

Next, by removing the photoresist layer 45 that was used as a mask during the plating, the formation of a contact 33 such as that shown in FIG. 7G is completed.

Next, as shown in FIG. 7H, solder resist 72 is formed so as to cover the wiring pattern 34 for the purpose of insulating and protecting the wiring pattern 34. Note that, although a description-thereof is omitted, it is preferable that solder resist is also formed on the wiring patterns in the first embodiment.

Next, as shown in FIG. 71, a connector 37 that has been separately prepared is bonded to the substrate 31 via the ACF 43. In addition, the driving IC 36 is mounted on the wiring patterns 34 and 35, and the portions of the terminals 38a and 38b of the driving IC 36 are sealed by the resin layer 39, thereby completing the formation of the inspection device 80 of the present embodiment.

In the present embodiment as well, it is possible to obtain the same effects as those obtained in the first and second embodiments, namely, it is possible to provide an inspection device that has a small number of component parts and that enables a high level of dimensional accuracy to be obtained by a simple manufacturing process, and that can be applied to general purpose components. Furthermore, in the case of the present embodiment, because the flexibility of the contacts 33 is further improved as a result of the hollow space 71 being provided beneath the contacts 33, it is possible to ensure more consistent contact even when irregularities or unevenness are present on the surface being inspected. Furthermore, even if the contacts 33 are displaced during the inspection, the displacement is accommodated. Therefore, the surface being inspected is resistant to damages, and the reliability of the inspection is improved. Moreover, because a method in which only the sacrifice layer 70 is removed selectively by etching is used as the method of forming the hollow space 71, it is possible to form the hollow space 71 using a comparatively simple method with excellent controllability.

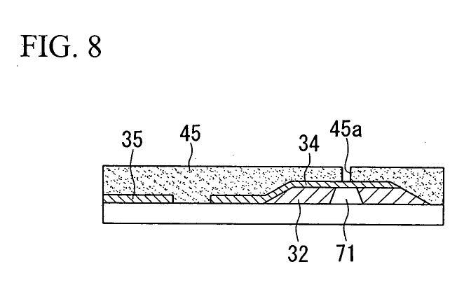

Note that it is possible to use the method described below as the method of forming the hollow space without using a sacrifice layer. As shown in FIG. 8, after the wiring patterns 34 and 35 have been formed, a resist layer 45 is formed. It is necessary to use a material for the resist layer 45 that has an appropriate etching resistance in accordance with the method for etching the stress relieving layer 32 that is performed next. For example, an organic resist or an inorganic resist such as SiO₂ can be used.

Next, openings 45a are formed in locations on the resist layer 45 where the hollow spaces are to be formed. The hollow spaces 71 are then formed by etching the stress relieving layer 32 through the openings 45a by wet etching or dry etching. In this method, because the etching progresses from the top portion of the stress relieving layer 32 through the openings 45a, at the least the top portion of the stress relieving layer 32 is removed and a wiring pattern 34 that is suspended is formed. Thereafter, the contacts 33 are formed inside the openings 45a. In this case, the openings 45 may be formed in advance at the size at which the contacts 33 are to be formed, or may be extended after the hollow space 71 has been formed in a separate process to the size at which the contacts 33 are to be formed.

Moreover, in the above-described structure, an example is described in which the hollow space 71 is formed by removing a part or all of the stress relieving layer 32 in an area beneath the contacts 33, however, instead of this structure, it is also possible to form the hollow space, for example, by forming a recess in the substrate 31 in an area beneath the contacts 33. In this case, for example, after the openings 45a and the hollow space 71 have been formed, recesses are formed in the substrate 31 in an area beneath the contacts 33 using an etchant that selectively etches the substrate 31. For the etchant, if the substrate 31 is silicon, it is possible to employ a wet etching method that uses an alkaline aqueous solution such as a potassium hydroxide aqueous solution, or to employ a dry etching method that uses plasma etching. Alternatively, it is also possible to employ a method in which, first, recesses are formed on the surface of the substrate 31, and after that, while maintaining the recesses as the hollow spaces, the stress relieving layer 32 and the wiring patterns and the like are formed on top of the recesses.

The stress relieving layer described in each of the above embodiments may be formed on the entire surface of the substrate 31 including the area beneath the contacts 33, or may be formed, for example, in a rectangular shape only in the area beneath the contacts 33.

It is also possible for the stress relieving layer to be formed more selectively in independent island shapes only under the contacts 33.

Moreover, the hollow space 71 described in the third embodiment may be formed, for example, in a rectangular shape only in an area beneath the contacts 33, or may be formed more selectively in independent island shapes only under the contacts 33.

Note that the technological scope of the present invention is not limited to the above-described embodiments and various modifications can be made without departing from the spirit or scope of the present invention. For example, in the above-described embodiments, an example is given of an inspection of a liquid crystal display device as an example of an electro-optical device, however, the present invention may also be applied to other electro-optical devices such as organic EL devices. Moreover, the inspection device of the present invention may also be applied to inspections of a variety of electrical characteristics in semiconductor devices such as LSI. Furthermore, in the above-described embodiments, an example is given of when a driving IC for a liquid crystal display device is mounted on a substrate, however, it is also possible to appropriately mount electronic components that are required for an inspection other than a driving IC. In addition to this, the specific description relating to the materials and dimensions for forming the inspection device shown in the above embodiments as well as the method for manufacturing the same may be altered as is appropriate.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as limited by the foregoing description and is only limited by the scope of the appended claims.

1. An inspection device comprising:
a substrate;
a stress relieving layer that is provided on the substrate;
a contact that is provided on the stress relieving layer; and
a wiring pattern that is electrically connected to the contact.

2. The inspection device according to claim 1, further comprising an electronic component used for an inspection that is mounted above the substrate, wherein the electronic component is electrically connected to the wiring pattern.

3. The inspection device according to claim 2, wherein the electronic component is an electronic component that is to be mounted on an object to be inspected after the object is inspected.

4. The inspection device according to claim 2, wherein the electronic component is mounted on the substrate with its face down.

5. The inspection device according to claim 1, wherein the substrate is a transparent substrate.

6. The inspection device according to claim 1, further comprising an electrical shielding layer that is provided on the substrate.

7. The inspection device according to claim 1, wherein the contact is tapered from an end thereof that is adjacent to the substrate to an opposing end thereof.

8. The inspection device according to claim 1, further comprising a connector that is provided above the substrate.

9. The inspection device according to claim 1, wherein a hollow space is provided beneath the contact.

10. The inspection device according to claim 9, wherein at least a portion of the stress relieving layer beneath the contact has been removed to define the hollow space.

11. The inspection device according to claim 9, wherein at least a portion of the substrate beneath the contact has been removed to define the hollow space.

12. An inspection device that is used for an inspection of electrical characteristics of an electronic device, comprising:
a substrate;
a stress relieving layer that is provided on the substrate;
a contact that is provided on the stress relieving layer;
a wiring pattern that is electrically connected to the contact; and
an electronic component for driving the electronic device, wherein the electronic component is provided on the substrate and is electrically connected to the wiring pattern.

13. A method for manufacturing an inspection device, comprising the steps of:
providing a substrate;
forming a stress relieving layer on a surface of the substrate;
forming a wiring pattern extending over the stress relieving layer on the surface of the substrate; and
forming a contact on the wiring pattern in an area above the stress relieving layer.

14. The method for manufacturing an inspection device, according to claim 13, wherein the step of forming a contact comprises the steps of:
forming a mask having a pattern in which a portion of an area on the wiring pattern that is above the stress relieving layer is opened; and
forming the contact by performing a plating process after the step of forming the masking.

15. The method for manufacturing an inspection device, according to claim 13, further comprising the steps of:
forming, before the step of forming the stress relieving layer, a sacrifice layer on the substrate at least in an area beneath where the contact is to be formed subsequently; and
forming, after the step of forming the stress relieving layer, a hollow space in an area beneath the contacts by selectively removing the sacrifice layer.

16. The method for manufacturing an inspection device, according to claim 13, further comprising the step of forming a hollow space by selectively removing at least a portion of the stress relieving layer that is beneath the contact.

17. The method for manufacturing an inspection device, according to claim 13, further comprising the step of forming a hollow space by selectively removing at least a portion of the substrate that is beneath the contact.

18. A method for manufacturing an electro-optical device, comprising the step of inspecting electrical characteristics using the inspection device described in claim 1.

19. A method for manufacturing a semiconductor device, comprising the step of inspecting electrical characteristics using the inspection device described in claim 1.
